(19) United States
(12) Patent Application Publication
(10) Pub. No.: US 2025/0107246 A1
(43) Pub. Date: Mar. 27, 2025

(54) ELECTROSTATIC DISCHARGE PROTECTION (ESD) CIRCUITRY INCLUDING ESD CIRCUIT AND OUTPUT DRIVER

(71) Applicant: Intel Corporation, Santa Clara, CA (US)

(72) Inventors: Krishna Bharath Kolluru, Hillsboro, OR (US); Archanna Srinivasan, San Jose, CA (US)

(21) Appl. No.: 18/372,260

(22) Filed: Sep. 25, 2023

(51) Int. Cl. H01L 27/02; H02H 9/04

(52) U.S. Cl. CPC H10D 89/811; H02H 9/046

(57) ABSTRACT

Some embodiments include an apparatus having a supply node, a conductive pad, and an electrostatic discharge (ESD) protection circuitry. The ESD protection circuitry includes a transistor including levels of semiconductor materials separated from each other and located one over another over a substrate. Respective portions of the levels of semiconductor materials form part of a channel, a source terminal, and a drain terminal of the transistor. The transistor includes a conductive material separated from the channel by a dielectric material and surrounding at least part of the channel. At least a portion of the conductive material forms part of a gate terminal of the transistor. The gate terminal is coupled to the supply node. The source terminal is coupled to the supply node. And the drain terminal is coupled to the conductive pad.

### BACKGROUND

Many electronic items (e.g., cellular phones, computers, and internet of things [IoT]) have at least one device (e.g., semiconductor chip) that includes conductive pads to transmit and receive information. In such a device, internal circuit elements coupled to the conductive pads are susceptible to damage caused by electrostatic discharge protection (ESD) events that may occur at the conductive pads during or after fabrication of the device. ESD protection circuitry is normally included in the device to protect internal circuit elements from damage by such ESD events. Some conventional ESD protection circuitries are formed by a combination of circuit elements that can include diodes, resistors, transistors, and clamp circuits. Such a combination can occupy a relatively large area in the device, leading to increased pad capacitance and higher cost in terms of area. Further, such a combination of components may be unsustainable in some packaging processes.

### BRIEF DESCRIPTION OF THE DRAWINGS

FIG. 1 shows an apparatus including a device having ESD protection circuitry, according to some embodiments described herein.

FIG. 2 shows another apparatus including a device having ESD protection circuitry, according to some embodiments described herein.

FIG. 3A, FIG. 3B, and FIG. 3C show different views of a structure of a transistor that can be included in ESD protection circuitry of FIG. 1 or FIG. 2, according to some embodiments described herein.

FIG. 4 shows an apparatus including devices having ESD protection circuitries, according to some embodiments described herein.

FIG. 5 shows a structure of an apparatus including devices having ESD protection circuitries, according to some embodiments described herein.

FIG. 6 shows a structure of another apparatus including devices having ESD protection circuitries, according to some embodiments described herein.

FIG. 7 shows an apparatus in the form of a system, according to some embodiments described herein.

### DETAILED DESCRIPTION

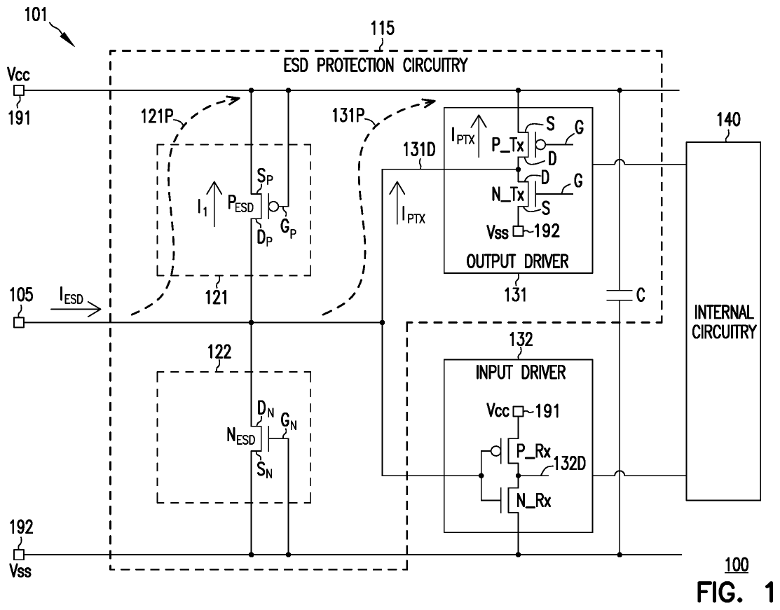

The techniques described herein involve ESD protection circuitry that includes ESD circuits, an output driver, or a combination of both. The described ESD protection circuitry may also include a capacitor (e.g., a decoupling capacitor). The described ESD protection circuitry may not include conventional diodes. In an example, the described ESD protection circuitry includes gated elements (e.g., transistors). The structure of circuit elements of the described ESD protection circuitry is area efficient which leads to reduced pad capacitance (which leads to improved device performance) and lower device cost in terms of area. Reduced area of the ESD protection circuitry can lead to higher density for other circuit elements in a device that can result in improved device performance. Further, the lack of conventional diodes in the described protection circuitry allows it to be sustainable in some packaging processes including wafer level packaging of multi-die device structures. These and other improvements and benefits of the described techniques are discussed in more detail below with reference to FIG. 1 through FIG. 7.

FIG. 1 shows an apparatus 100 including a device 101 having ESD protection circuitry 115, according to some embodiments described herein. In an example, device 101 can include or can be part of an integrated circuit (IC) die (IC chip). In an example, apparatus 100 can include or be included in an electronic device or system, such as a computer (e.g., desktop, laptop, or notebook), a tablet, a cellular phone, a system on chip (SoC), system in package (SiP), or other electronic devices or systems.

As shown in FIG. 1, apparatus 100 can include a conductive pad 105, a supply node 191, a supply node 192, and a capacitor (e.g., decoupling capacitor) C including respective capacitor terminals (e.g., capacitor plates) coupled to supply nodes 191 and 192. Supply nodes 191 and 192 can be coupled to or can be part of the supply voltage (e.g., supply voltage rails) of apparatus 100. For example, as shown in FIG. 1, supply nodes 191 and 192 can be coupled to or can be part of supply voltages (e.g., supply voltages Vcc and Vss, respectively) of apparatus 100. Supply voltage Vcc can include a positive supply voltage. Supply voltage Vss can include ground potential.

As shown in FIG. 1, device 101 can include an output driver (e.g., output buffer) 131 and input driver (e.g., input buffer) 132, and internal circuitry 140. Internal circuitry 140 can include circuitry to provide and process information (e.g., output data and input data). Device 101 can include a circuit (ESD circuit) 121 and a circuit (ESD circuit) 122. As shown in FIG. 1, circuit 121, circuit 122, output driver 131, and capacitor C can be part of (e.g., can be included in) ESD protection circuitry 115 to provide ESD protection to circuit elements (e.g., circuit elements coupled to conductive pad 105) in part of device 101.

Conductive pad (e.g., conductive node) 105 can include an input/output (I/O) pad (e.g., I/O node) that can be used by device 101 to transmit information (e.g., output data) or to receive information (e.g., input data). Apparatus 100 can include a transmit mode to transmit information (e.g., output data) to another device (not shown in FIG. 1) through conductive pad 105. Apparatus 100 can include a receive mode to receive information (e.g., input data) at conductive pad 105 in which the input data can be sent to apparatus 100 by another device (not shown in FIG. 1). Apparatus 100 can switch between the transmit mode and the receive mode and operate in the transmit mode and receive mode one at a time.

Output driver 131 can operate to transmit information (e.g., output data) from internal circuitry 140 to conductive pad 105. Input driver 132 can operate to receive information (e.g., input data) at conductive pad 105 and provide the received information to internal circuitry 140. For simplicity, FIG. 1 omits detailed connections (e.g., circuit paths and circuit elements) between internal circuitry 140 and output driver 131 and between internal circuitry 140 and input driver 132.

As shown in FIG. 1, output driver 131 can include a transistor P_Tx and a transistor N_Tx. Transistor P_Tx can include (e.g., can be) a p-type transistor. Transistor N_Tx can include (e.g., can be) an n-type transistor. Input driver 132 can include a transistor P_Rx and a transistor N_Rx. Transistor P Rx can include (e.g., can be) a p-type transistor. Transistor N_Rx can include (e.g., can be) an n-type transistor.

As shown in FIG. 1, in output driver 131, each of transistor P_Tx and transistor N_Tx can include a gate terminal G, a source terminal S, and a drain terminal D. Source terminal S and drain terminal D of transistor P_Tx can be coupled to supply node 191 and conductive pad 105, respectively. Source terminal S and drain terminal D of transistor N_Tx can be coupled to supply node 192 and conductive pad 105, respectively. Output driver 131 can include input nodes coupled to respective gate terminal G of transistors P_Tx and N_Tx, an output node 131D coupled to conductive pad 105. As shown in FIG. 1, drain terminals D of transistor P_Tx and transistor N_Tx can form (e.g., can be part of) output node 131D. For simplicity, FIG. 1 omits other circuit elements of output driver 131 that are coupled to gate terminals G of transistors P_Tx and N_Tx to provide signals (e.g., voltage signals) to gate terminals G of transistors P_Tx and N_Tx. Gate terminals G of transistors P_Tx and N_Tx can be responsive to respective voltage signals in a transmit mode of apparatus 100 to allow output driver 131 to provide information (e.g., output data) to conductive pad 105. The value (output data value) of information (e.g., output data) at conductive pad 105 can be based on the values of the voltage signals at gate terminals G of transistors P_Tx and N_Tx. The value of the voltage signals provided to gate terminals G of transistors P_Tx and N_Tx can be based on the values of the information to be provided to output node 132D.

For example, in a transmit mode of apparatus 100, gate terminals G of transistors P_Tx and N_Tx can be responsive to respective voltage signals and turn on transistor P_Tx and turn off transistor N_Tx. In this example, output driver 131 can a provide information (e.g., a bit of output data) to conductive pad 105 in which the information can have a value (e.g., logic one) based on the value of the voltage (e.g., voltage Vcc) at supply node 191.

In another example, in a transmit mode of apparatus 100, gate terminals G of transistors P_Tx and N_Tx can be responsive voltage signals and turn off transistor P_Tx and turn on transistor N_Tx. In this example, output driver 131 can a provide information (e.g., a bit of output data) to conductive pad 105 in which the information can have a value (e.g., logic zero) based on the value of the voltage (e.g., voltage Vss) at supply node 192.

As shown in FIG. 1, in input driver 132, transistors P_Rx and N_Rx can include respective gate terminals (not labeled) coupled to conductive pad 105. Input driver 132 can include an input node (formed by the gate terminals of transistors P_Rx and N_Rx) coupled to conductive pad 105. Transistors P_Rx and N_Rx can include respective source terminals (not labeled) coupled to supply node 191 and supply node 192, respectively, and respective drain terminals (not labeled) coupled to an output node 132D of input driver 132. For simplicity, FIG. 1 omits other circuit elements of input driver 132 that are coupled between output node 132D and internal circuitry 140. The gate terminals (not labeled) of transistors P_Rx and N_Rx can be responsive to the voltage signal at conductive pad 105 in a receive mode of apparatus 100 to allow input driver 132 to receive information (e.g., input data) at conductive pad 105 and provide information (e.g., input data) to output node 132D. Information at output node 132D can be passed to internal circuitry 140 by circuit elements (not shown) coupled to output node 132D. The value (input data value) of information (e.g., input data) at output node 132D can be based on the value of the voltage signal at conductive pad 105.

For example, in a receive mode of apparatus 100, the gate terminals of transistors P_Rx and N_Rx can be responsive to a voltage signal and turn on transistor P_Rx and turn off transistor N_Rx. In this example, input driver 132 can provide information (e.g., a bit of output data) to output node 132D in which the information can have a value (e.g., logic one) based on the value of the voltage (e.g., voltage Vcc) at supply node 191. In another example, in a receive mode of apparatus 100, the gate terminals of transistors P_Rx and N_Rx can be responsive to another voltage signal and turn off transistor P_Rx and turn on transistor N_Rx. In this example, input driver 132 can provide information (e.g., a bit of output data) to output node 132D in which the information can have a value (e.g., logic zero) based on the value of the voltage (e.g., voltage Vss) at supply node 192.

As shown in FIG. 1, circuits 121 and 122 of ESD protection circuitry 115 can include transistor P_{ESD} and transistor N_{ESD}, respectively. Transistor P_{ESD} can include (e.g., can be) a p-type transistor. Transistor N_{ESD} can include (e.g., can be) an n-type transistor. Transistor P_{ESD} can have the same type (e.g., p-type) and same structure (physical structure) as transistor P_Tx of output driver 131. Alternatively, transistors P_{ESD} and P_Tx can have different structures (physical structures). Transistor N_{ESD} can have the same type (e.g., n-type) and same structure (physical structure) as transistor N_Tx of output driver 131. Alternatively, transistors N_{ESD} and N_Tx can have different structures (physical structures).

As shown in FIG. 1, transistor P_{ESD} can include a gate terminal G_{P} coupled to supply node 191, a source terminal S_{P} coupled to supply node 191, and a drain terminal D_{P} coupled to conductive pad 105. Transistor N_{ESD} can include a gate terminal G_{N} coupled to supply node 192, a source terminal S_{N} coupled to supply node 192, and a drain terminal D_{N} coupled to conductive pad 105.

As shown in FIG. 1, ESD protection circuity 115 can include a circuit path (e.g., current path) 121P between conductive pad 105 and supply node 191 through circuit 121. Source terminal S_{P} and drain terminal D_{P} of transistor P_{ESD} can be part of circuit path 121P.

ESD protection circuity 115 can also include a circuit path (e.g., current path) 131P between conductive pad 105 and supply node 191 through transistor P_Tx of output driver 131. Source terminal S and drain terminal D of transistor P_Tx can be part of circuit path 131P.

ESD protection circuitry 115 can use circuit 121, output driver 131, and capacitor C to protect circuit elements (e.g., input driver 132) coupled to conductive pad 105 in response to an ESD event occurred at conductive pad 105 during or after fabrication apparatus 100. For example, an ESD event having a positive voltage (e.g., 5 volts or greater) may occur at conductive pad 105 during or after fabrication apparatus 100. Such an ESD event may generate a relative high amount of charge at conductive pad 105. The charge can damage circuit elements (e.g., gate oxide of transistors P_Rx and N_Rx of input driver 132) of device 101 that are coupled to conductive pad 105. Circuit path 121P (or the combination of circuit paths 121P and 131P) allows charge at conductive pad 105 to discharge (e.g., discharge to supply node 191) in the form of current (e.g., ESD current) IESD from conductive pad 105 to supply node 191 through circuit path 121P as current I₁. Part of charge from conductive pad 105 (part of current I_{ESD}) may also discharge to supply node 191 through circuit path 131P as current I_{PTX}.

In another example, in another ESD event (e.g., a relatively large amount of charge accumulated at conductive pad 105), ESD protection circuitry 115 can operate to discharge an ESD current (not shown) from conductive pad 105 to supply node 192 through circuit 122 (e.g., through transistor N_{ESD}) or through a combination of circuits 122 and output driver 131 (e.g., through transistor N_Tx) to provide ESD protection to apparatus 100.

In FIG. 1, capacitor C, circuits 121 and 122, and output driver 131 can be structured to be large enough (to have appropriate sizes) to provide ESD protection for part of apparatus 100 (e.g., for circuit elements coupled to conductive pad 105). The sizes of circuits 121 and 122 and the size of output driver 131 can be selected (adjusted) to maintain enough ESD protection. For example, in some cases, the size of output driver 131 can be structured to be relatively small if the drive strength of output driver 131 is selected to be low (e.g., due to shorter length of signal routing paths). However, such a small size of output driver 131 may not be enough to provide ESD protection. In this example, the size of circuits 121 and 122 can be increased to compensate the smaller size of output driver 131 in order to allow the combination of circuits 121 and 122 and output driver 131 provide enough ESD protection to meet certain specifications.

In an alternative structure of apparatus 100, one or more of circuit elements of ESD protection circuitry 115 can be omitted and the remaining circuit elements can be configured (e.g., sized) to provide enough ESD protection. For example, in an alternative structure of apparatus 100, circuits 121 and 122 (and optionally capacitor C) can be omitted from ESD protection circuitry 115. In such an alternative structure, the size output driver 131 (e.g., the size of transistors P_Tx and N_Tx) can be structured to be large enough to provide ESD protection. For example, the size of output driver 131 in the omission of circuits 121 and 122 can be relatively larger than the size of output driver 131 when circuits 121 and 122 output driver 131 are included in ESD protection circuitry 115.

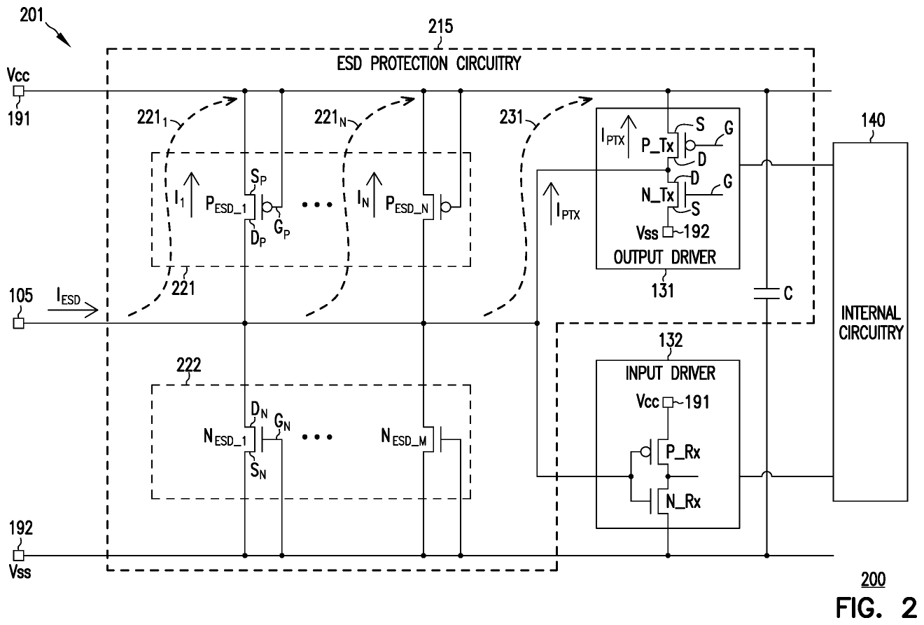

FIG. 2 shows an apparatus 200 including a device 201 including ESD protection circuitry 215, according to some embodiments described herein. Apparatus 200 and device 201 can include circuit elements that are similar to or the same as circuit elements of apparatus 100 and device 101, respectively. For simplicity, similar or the same elements have the same labels and their descriptions are not repeated. Differences between apparatuses 100 and 200 include the number of transistors in ESD protection circuitry 215 of device 201 in FIG. 2.

As shown in FIG. 2, ESD protection circuitry 215 can include circuits (ESD circuits) 221 and 222 in which each of circuits 221 and 222 can include transistors coupled to conductive pad 105, supply node 191, and 192 in ways similar to (or the same as) transistors P_{ESD} and N_{ESD} of circuits 121 and 122. For example, circuit 221 can include transistors P_{ESD_1} through P_{ESD_N} where each can be coupled to conductive pad 105 and supply node 191 in ways similar to that of transistor P_{ESD} of FIG. 1. In another example, circuit 222 can include transistors N_{ESD_1} through N_{ESD_M} where each can be coupled to conductive pad 105 and supply node 192 in ways similar to that of transistor N_{ESD} of FIG. 1. The number (e.g., N transistors) of transistors P_{ESD_1} through P_{ESD_N} of circuit 221 can be the same as or different from the number (e.g., M transistors) transistors N_{ESD_1} through N_{ESD_M} of circuit 222.

As shown in FIG. 2, transistors P_{ESD_1} through P_{ESD_N} can form respective parallel circuit paths (e.g., current paths) 221₁ through 221_{N} between conductive pad 105 and supply node 191. Transistors N_{ESD_1} through N_{ESD_M} can form parallel circuit paths (not labels) between conductive pad 105 and supply node 192. In an ESD event (e.g., a relatively large negative charge accumulated at conductive pad 105), ESD protection circuitry 215 can operate to discharge an ESD current (e.g., current I_{ESD}) from conductive pad 105 to supply node 191 through circuit paths 221₁ through 221_{N} in the form of currents I₁ through I_{N}, respectively, or through the combination of circuit paths 221₁ through 221_{N} and circuit path 231 in the form of current I₁ through I_{N} and current I_{PTX}, respectively, to provide ESD protection to apparatus 200.

In another ESD event (e.g., a relatively large amount of charge accumulated at conductive pad 105), ESD protection circuitry 215 can operate to discharge an ESD current (not shown) from conductive pad 105 to supply node 192 through circuit 222 (e.g., through transistors N_{ESD_1} through N_{ESD_M}) or through a combination of circuits 222 and output driver 131 (e.g., through transistor N_Tx) to provide ESD protection to apparatus 200.

As described above with reference to FIG. 1 and FIG. 2, circuits 121 and output driver 131 can include p-type transistors. Circuits 122 and input driver 132 can include n-type transistors. An example of a p-type transistor includes a p-type field-effect transistor (FET), such as p-type metal-oxide semiconductor (PMOSFET or PMOS). Other p-type transistors can be used. An example of an n-type transistor includes n-type FET, such as n-type metal-oxide semiconductor (NMOSFET or NMOS). Other n-type transistors can be used. The structures of p-type transistor and the n-type transistor can include gated-node-area charge (GNAC) device structures, finFET device structures, gate-all-around FET (GAAFET) device structures, or other device structures.

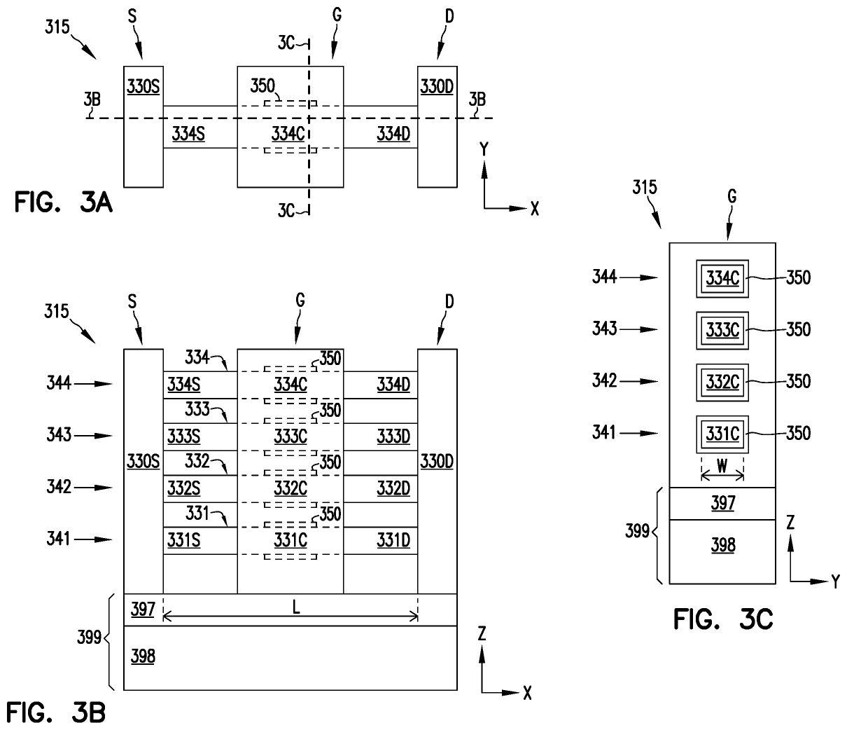

FIG. 3A, FIG. 3B, and FIG. 3C show different views of a structure of a transistor 315 that can be included in ESD protection circuitry 115 of FIG. 1 or ESD protection circuitry 215 of FIG. 2, according to some embodiments described herein. FIG. 3A shows a top view (plan view) in the X-direction and the Y-direction of transistor 315. FIG. 3B shows a side view (e.g., cross section) in the X-direction and Z-direction along line 3B of transistor 315 of FIG. 3A. FIG. 3C shows a side view (e.g., cross section) in the Y-direction and Z-direction along line 3C of transistor 315 of FIG. 3A.

As shown in FIG. 3B, transistor 315 can include a substrate 399 having a portion 398 and a portion 397 formed over (e.g., formed on) portion 398. Portion 398 can include (e.g., can be formed from) a semiconductor material (e.g., silicon). Portion 398 can be called a bulk portion of substrate 399. Portion 397 can include (e.g., can be formed from) a dielectric material (e.g., an oxide of silicon).

As shown in FIG. 3B and FIG. 3C, transistor 315 can include levels (layers) of semiconductor materials 331, 332, 333, and 334 separated from each other and located one over another (e.g., stacked one over another) in different levels 341, 342, 343, and 344 (in the Z-direction) over substrate 399.

Levels of semiconductor materials 331, 332, 333, and 334 can include respective portions 331S, 332S, 333S, and 334S, respective portions 331D, 332D, 333D, and 334D, and respective portions 331C, 332C, 333C, and 334C. Transistor 315 can include portions (e.g., conductive contact) 330S and 330D. Portions 330S and 330D can include a conductive material.

As shown in FIG. 3B, portion 330S can be coupled to portions 331S, 332S, 333S, and 334S, such that portions 331S, 332S, 333S, and 334S can be electrically coupled to each other through portion 330S. As shown in FIG. 3B, portion 330D can be coupled to portions 331D, 332D, 333D, and 334D, such that portions 331D, 332D, 333D, and 334D can be electrically coupled to each other through portion 330D.

As shown in FIG. 3B, transistor 315 can include a source terminal S, a drain terminal D, and a gate terminal G. Gate terminal G can include a conductive material (e.g., metal or other conductive material). Portion 330S and portions 331S, 332S, 333S, and 334S can form part of source terminal S of transistor 315. Portion 330D and portions 331D, 332D, 333D, and 334D can form part of drain terminal D of transistor 315. Portions 331C, 332C, 333C, and 334C can form part of the channel (transistor channel) of transistor 315.

Since portion 397 is between transistor 315 and portion 398, the elements (e.g., source and drain terminals and the channel) of transistor 315 may not be coupled to portion 398 (e.g., the bulk portion or semiconductor material portion) of substrate 399. Thus, in the structure of transistor 315, there may be no electrical connections (lack of electrical connections) between the elements (e.g., source and drain terminals and the channel) of transistor 315 and portion 398. For example, as shown in FIG. 3C and FIG. 3B, the channel (e.g., portions 331C, 332C, 333C, and 334C) of transistor 315 is uncoupled to portion 398 of substrate 399. The source terminal S (e.g., portions 331S, 332S, 333S, and 334S) of transistor 315 is uncoupled to portion 398 (e.g., semiconductor material portion) of substrate 399. Drain terminal D (e.g., portions 331D, 332D, 333D, and 334D) of transistor 315 is uncoupled to portion 398 of substrate 399.

As shown in FIG. 3B, each of levels of semiconductor materials 331, 332, 333, and 334 can include a length L in the X-direction between source terminal S and drain terminal D. As shown in FIG. 3C, each of levels of semiconductor materials 331, 332, 333, and 334 can include width W in the Y-direction (which is perpendicular to the X-direction).

As shown in FIG. 3C, transistor 315 can include a dielectric material 350 surrounding respective portions 331C, 332C, 333C, and 334C. Gate terminal G (a portion of the conductive material of gate terminal G) can be separated from the channel (e.g., portions 331C, 332C, 333C, and 334C) of transistor 315 by respective dielectric materials 350. As shown in FIG. 3C, gate terminal G can surround dielectric materials 350 and the channel (e.g., surround four sides of the channel in the view of FIG. 3C) of transistor 315.

As shown in FIG. 3B and FIG. 3C, portions 331C, 332C, 333C, and 334C may not be coupled to (e.g., are electrically isolated from) portion 398 (e.g., bulk portion) of substrate 399. Similarly, portion 330S and portions 331S, 332S, 333S, and 334S (part of source terminal S) may not be coupled to (e.g., are electrically isolated from) portion 398 of substrate 399. Portion 330D and portions 331D, 332D, 333D, and 334D (part of drain terminal D) may not be coupled to (e.g., are electrically isolated from) portion 398 of substrate 399.

FIG. 3A, FIG. 3B, and FIG. 3C show transistor 315 including four levels of semiconductor materials 331, 332, 333, and 334 (which are part of the channel and source and drain terminals) of transistor 315. However, the number of levels of semiconductor materials can vary.

As described above, transistor 315 can be used as the transistors for ESD protection circuitries described herein (e.g., ESD protection circuitry 115 of FIG. 1 or ESD protection circuitry 125 of FIG. 2). For example, the structure of transistor 315 of FIG. 3A, FIG. 3B, and FIG. 3C can be configured as a p-type transistor that can be used as transistor P_{ESD} and P_Tx of ESD protection circuitry 115 of FIG. 1. In this example, gate, source, and drain terminals G, S, and D transistor 315 can correspond to gate, source, and drain terminals G_{P}, S_{P}, and D_{P}, respectively, of transistor P_{ESD} of FIG. 1 or to gate, source, and drain terminals G, S, and D, respectively, of transistor P_Tx of FIG. 1.

In another example, the structure of transistor 315 of FIG. 3A, FIG. 3B, and FIG. 3C can be configured as an n-type transistor that can be used as transistor N_{ESD} and N_Tx of ESD protection circuitry 115 of FIG. 1. In this example, gate, source, and drain terminals G, S, and D of transistor 315 can correspond to gate, source, and drain terminals G_{N}, S_{N}, and D_{N}, respectively, of transistor N_{ESD} of FIG. 1 or correspond to gate, source, and drain terminals G, S, and D, respectively, of transistor N_Tx of FIG. 1.

Improvement and benefits of including transistor 315 in ESD protection circuitries described herein (e.g., ESD protection circuitry 115 of FIG. 1 or ESD protection circuitry 125 of FIG. 2) are described below.

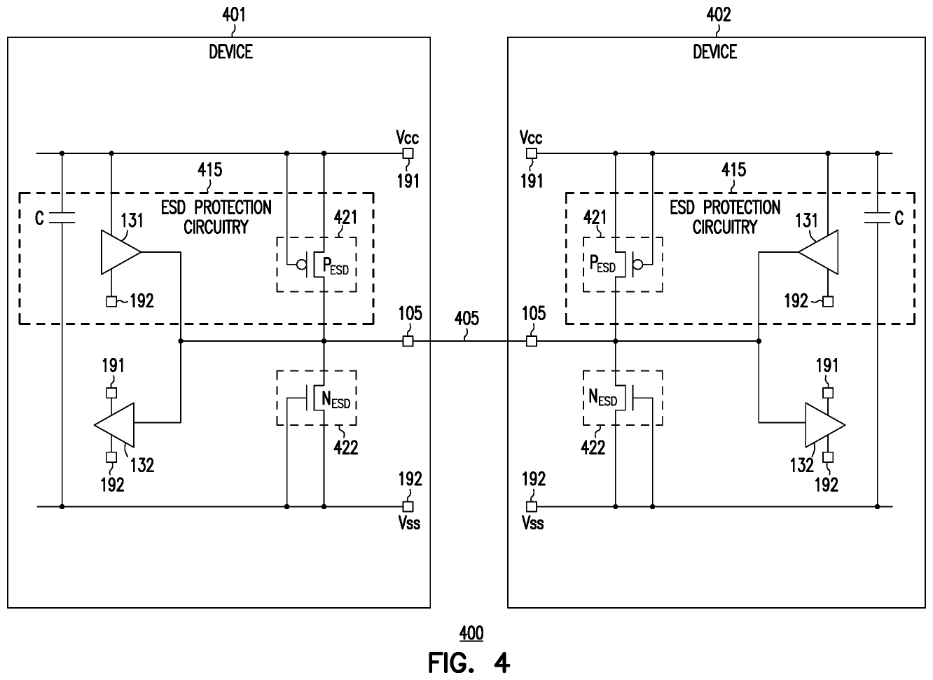

FIG. 4 shows an apparatus 400 including devices 401 and 402 having respective ESD protection circuitries 415, according to some embodiments described herein. Apparatus 300 can include or can be part an IC package, a SoC, a SiP, or other electronic devices or systems. Each of devices 401 and 402 can include an IC die where a respective ESD protection circuitry 415 is located. Each of device 401 and 402 can include a memory device, a logic processing device (e.g., field-programmable gate array [FPGA]), or other IC devices. As shown in FIG. 4, each of devices 401 and 402 can include circuits elements that are similar to or the same as circuit elements of apparatus 100. For simplicity, similar or the same elements have the same labels and their descriptions are not repeated. Each ESD protection circuitry 415 can include (e.g., can correspond to) ESD protection circuitry 115 of FIG. 1 or ESD protection circuitry 215 of FIG. 2.

As shown in FIG. 4, ESD protection circuitry 415 in each of devices 401 and 402 can include circuits (ESD circuits) 421 and 422 in which each of circuits 421 and 422 can include at least one transistor P_{ESD} and at least one transistor N_{ESD} like transistors P_{ESD} and N_{ESD} of circuits 121 and 122 of FIG. 1 or circuits 221 and 222 of FIG. 2. Apparatus 400 can include a conductive connection 405 coupled to conductive pad 105 of device 401 and conductive pad 105 of device 402. Conductive connection 405 can provide electrical connection (e.g., die to die connection) between respective IC dies of devices 401 and 402.

ESD protection circuitries 415 can operate to provide ESD protection to circuit elements of respective devices 401 and 402 similar that of ESD protection circuitry 115 of FIG. 1 or ESD protection circuitry 215 of FIG. 2 providing ESD protection for devices 101 and 201, respectively.

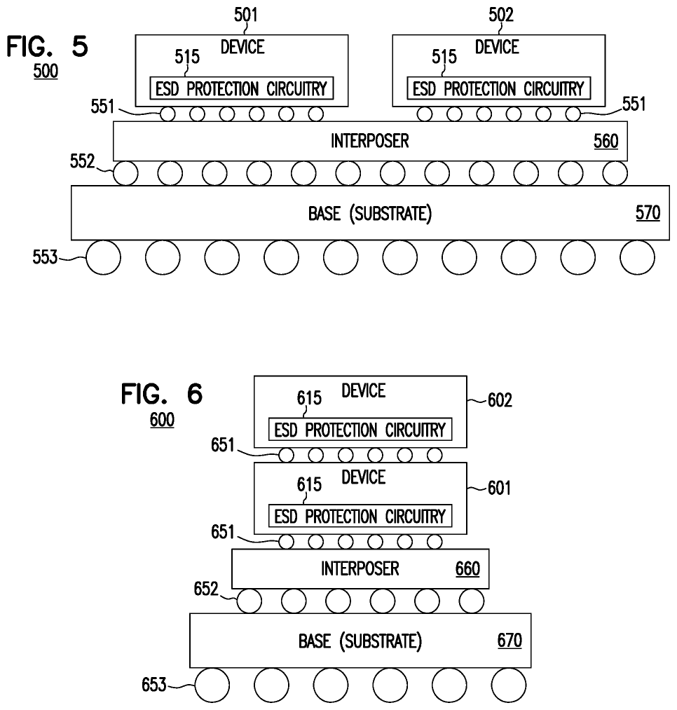

FIG. 5 shows a structure of an apparatus 500 including devices 501 and 502 having respective ESD protection circuitries 515, according to some embodiments described herein. Apparatus 500 can include or can be part an IC package, a SoC, a SiP, or other electronic devices or systems. Each of devices 501 and 502 can include an IC die that can include a respective ESD protection circuitry 515 and other circuitries (not shown). Each of device 501 and 502 can include a memory device, a logic processing device (e.g., field-programmable gate array [FPGA]), or other IC devices. Each ESD protection circuitry 515 can include (e.g., can correspond to) ESD protection circuitry 115 of FIG. 1 or ESD protection circuitry 215 of FIG. 2.

As shown in FIG. 5, each of devices 501 and 502 can include conductive connections 551 to allow electrical communication to and from each of devices 501 and 502. Example of conductive connections 551 include conductive bumps (e.g., micro-bumps). One or more of conductive connections 551 can correspond to conductive pad 105 of FIG. 1 or FIG. 2.

As shown in FIG. 5, apparatus 500 can include a base (e.g., a package substrate) 570, and interposer 560 located over (e.g., stacked over) base 570. Devices 501 and 502 can be located side by side (e.g., located in the same plane [e.g., X-Y plane]) on interposer 560.

Apparatus 500 can include conductive connections (e.g., conductive bumps) 552 between interposer 560 and base 570 to allow electrical communication between interposer and base 570. Apparatus 500 can include conductive connections (e.g., conductive balls) 553 to allow apparatus 500 to allow electrical communication between base 570 and other devices (not shown) coupled to conductive connections 553. Devices 501 and 502 can communicate with other devices (not shown) through conductive connections 551, 552, and 553 and other conductive connections (e.g., conductive vias) in interposer 560 and base 570.

In FIG. 5, ESD protection circuitries 515 can operate like ESD protection circuitry 115 of FIG. 1 or ESD protection circuitry 215 of FIG. 2 to provide ESD protection to circuit elements of respective devices 501 and 502. For example, ESD protection circuitry 515 of device 501 can provide ESD protection to circuit elements coupled to conductive connections 551 of device 501. Similarly, ESD protection circuitry 515 of device 502 can provide ESD protection to circuit elements coupled to conductive connections 551 of device 502.

FIG. 6 shows a structure of an apparatus 600 including devices 601 and 602 having respective ESD protection circuitries 615, according to some embodiments described herein. Apparatus 600 can include or can be part an IC package, a SoC, a SiP, or other electronic devices or systems. Each of devices 601 and 602 can include an IC die that includes a respective ESD protection circuitry 615 and other circuitries (not shown). Each of device 601 and 602 can include a memory device, a logic processing device (e.g., field-programmable gate array (FPGA)), or other IC devices. Each ESD protection circuitry 615 can include (e.g., can correspond to) ESD protection circuitry 115 of FIG. 1 or ESD protection circuitry 215 of FIG. 2.

As shown in FIG. 6, each of devices 601 and 602 can include conductive connections 651 to allow electrical communication to and from each of devices 601 and 602. Example of conductive connections 651 include conductive bumps (e.g., micro-bumps). One or more of conductive connections 651 can correspond to conductive pad 105 of FIG. 1 or FIG. 2.

As shown in FIG. 6, apparatus 600 can include a base (e.g., a package substrate) 670, and interposer 660 located over (e.g., stacked over) base 670. Devices 601 and 602 can be stacked one over another over interposer 660.

Apparatus 600 can include conductive connections (e.g., conductive bumps) 652 between interposer 660 and base 670 to allow electrical communication between interposer and base 670. Apparatus 600 can include conductive connections (e.g., conductive balls) 653 to allow apparatus 600 to allow electrical communication between base 670 and other devices (not shown) coupled to conductive connections 653. Devices 601 and 602 can communicate with other devices (not shown) through conductive connections 651, 652, and 653 and other conductive connections (e.g., conductive vias) in interposer 660 and base 670.

In FIG. 6, ESD protection circuitries 615 can operate like ESD protection circuitry 115 of FIG. 1 or ESD protection circuitry 215 of FIG. 2 to provide ESD protection to circuit elements of respective devices 601 and 602. For example, ESD protection circuitry 615 of device 601 can provide ESD protection to circuit elements coupled to conductive connections 651 of device 601. Similarly, ESD protection circuitry 615 of device 602 can provide ESD protection to circuit elements coupled to conductive connections 651 of device 602.

As mentioned above, the transistors (e.g., transistors P_{ESD} and P_Tx) of ESD protection circuitry 115 or ESD protection circuitry 215 can include different structures. However, using the structure of transistor 315 FIG. 3A, FIG. 3B, and FIG. 3C) for the transistors of ESD protection circuitry herein provide improvements and benefits over other structures and over some conventional ESD protection circuitries. For example, some structures (e.g., P-N diode structures other transistors having bulk connections) in some conventional ESD protection circuitries may have connection between portions of the ESD elements (e.g., ESD diodes or ESD transistors) and the bulk of a substrate (e.g., silicon substrate). Such a connection may create parasitic circuit elements (e.g., parasitic diodes or parasitic transistor). Such parasitic elements can result in a latch-up (e.g., short circuit) that can degrade or destroy the ESD protection function of the ESD protection circuitries.

As described above, transistor 315 (which can be used as the transistors of the described ESD protection circuitries) may not include a connection (e.g., electrical connection) between circuit elements (e.g., channel, and source and drain terminals) of transistor 315 and the bulk (e.g., portion 398) of substrate 399. The lack of such a connection can prevent creation of parasitic elements in the ESD protection circuitries described herein (e.g., ESD protection circuitries 115, 215, 415, 515, and 615). The absence of such parasitic elements can improve the function and reliability of the described ESD protection circuitries.

Further, the structure of the ESD protection circuitries described herein (e.g., ESD protection circuitries 115, 215, 415, 515, and 615) may occupy a smaller area of total I/O (e.g., ESD and drivers) area of the described device (e.g., device 101, 201, 401, 402, 501, 502, 601, and 602) in comparison with the structure of some conventional ESD protection circuitries. Smaller area can lead to improvements and benefits including a lower pad capacitance, and a higher number of circuit elements (e.g., higher number of logic elements). These improvements and benefits associated with the smaller area of the described ESD protection circuitries can also lead to improved performance of the device (e.g., device 101, 201, 401, 402, 501, 502, 601, and 602) that includes the described ESD protection circuitries. In a multi-die structure (e.g., apparatus 500 or 600), die-to-die I/O density can also be increased that can also lead to improved performance of the devices (e.g., devices 101, 201, 401, 402, 501, 502, 601, and 602) in multi-die structure.

Moreover, some conventional ESD protection circuitries include ESD diodes. Such ESD diodes can occupy a relatively large I/O area of the device (e.g., IC die) that makes some fabrication processes (e.g., wafer level packaging) unsustainable. In contrast, the ESD protection circuitry described herein (e.g., ESD protection circuitries 115, 215, 415, 515, and 615) may not include a diode (lacks an ESD diode) coupled between conductive pad 105 and supply node 191 and between conductive pad 105 and supply node 192. Such an ESD diode typically has at least one portion (e.g., p-type doped region, n-type doped region, or both) coupled to the bulk of a silicon substrate. The lack of such a diode allows the described ESD protection circuitries (e.g., ESD protection circuitries 115, 215, 415, 515, and 615) to have a reduced area in comparison with some conventional ESD protection circuitries that includes ESD diodes. Further, the lack of such ESD diodes allows the devices (e.g., devices 101, 201, 401, 402, 501, 502, 601, and 602) to be included in a multi-die structure and sustainable in fabrication processes such as wafer level packaging. Moreover, the mentioned improvements and benefits of associated with the described ESD protection circuitries (e.g., ESD protection circuitries 115, 215, 415, 515, and 615) can allow a device that includes the described ESD protection circuitries to be suitable for many packaging techniques, such as 2.5D packaging (e.g., apparatus 500), 3D packaging (e.g., apparatus 600), or other packing techniques.

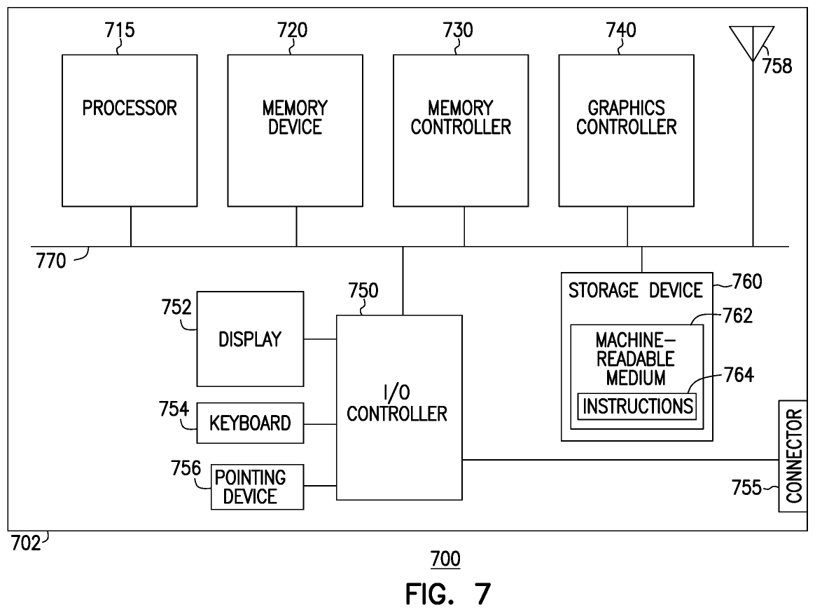

FIG. 7 shows an apparatus in the form of a system (e.g., electronic system) 700, according to some embodiments described herein. System 700 can be viewed as a machine. System (e.g., machine) 700 can include or be included in a computer, a cellular phone, or other electronic systems. As shown in FIG. 7, system 700 can include components (e.g., devices) located on a circuit board (e.g., PCB) 702. The components can include a processor (e.g., a hardware processor) 715, a memory device 720, a memory controller 730, a graphics controller 740, an I/O controller 750, a display 752, a keyboard 754, a pointing device 756, at least one antenna 758, a storage device 760, and a bus 770. Bus 770 can include conductive lines (e.g., metal-based traces on a circuit board 702 where the components of system 700 are located).

System 700 may be configured to perform one or more of the methods and/or operations described herein. At least one of the components of system 700 (e.g., at least one of processor 715, memory device 720, memory controller 730, graphics controller 740, and I/O controller 750) can include at least one of the devices described herein (e.g., devices 101, 201, 401, 402, 501, 502, 601, and 602) in which the device can include the described ESD protection circuitry (e.g., ESD protection circuitries 115, 215, 415, 515, and 615).

In FIG. 7, processor 715 can include a general-purpose processor or an application specific integrated circuit (ASIC). Processor 715 can include a central processing unit (CPU) and processing circuitry. Graphics controller 740 can include a graphics processing unit (GPU) and processing circuitry. Memory device 720 can include a dynamic random-access memory (DRAM) device, a static random-access memory (SRAM) device, a flash memory device, phase change memory, or a combination of these memory devices, or other types of memory. FIG. 7 shows an example where memory device 720 is a stand-alone memory device separated from processor 715. In an alternative structure, memory device 720 and processor 715 can be located on the same integrated circuit (IC) chip (e.g., a semiconductor die or IC die). In such an alternative structure, memory device 720 is an embedded memory in processor 715, such as embedded DRAM (eDRAM), embedded SRAM (eSRAM), embedded flash memory, or another type of embedded memory.

Storage device 760 can include drive unit (e.g., hard disk drive (HHD), solid-state drive (SSD), or another mass storage device). Storage device 760 can include a machine-readable medium 762 and processing circuitry. Machine-readable medium 762 can store one or more sets of data structures or instructions 764 (e.g., software) embodying or used by any one or more of the techniques or functions described herein. Instructions 764 may also reside, completely or at least partially, within memory device 720, memory controller 730, processor 715, or graphics controller 740 during execution thereof by system (e.g., machine) 700.

In an example, one of (or any combination of) processor 715, memory 720, memory controller 730, graphics controller 740, and storage device 760 may constitute machine-readable media. Non-limiting machine-readable medium examples may include solid-state memories and optical and magnetic media. Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

FIG. 7 shows machine-readable medium 762 as a single medium as an example. However, the term “machine-readable medium” may include a single medium or multiple media (e.g., a centralized or distributed database, and/or associated caches and servers) configured to store instructions 764. Further, the term “machine-readable medium” may include any medium that is capable of storing, encoding, or carrying instructions for execution by system 700 and that causes system 700 to perform any one or more of the techniques of the present disclosure, or that is capable of storing, encoding or carrying data structures used by or associated with such instructions. In some examples, machine-readable media may include non-transitory machine-readable media. In some examples, machine-readable media may include machine-readable media that is not a transitory propagating signal.

Display 752 can include a liquid crystal display (LCD), a touchscreen (e.g., capacitive or resistive touchscreen), or another type of display. Pointing device 756 can include a mouse, a stylus, or another type of pointing device. In some structures, system 700 does not have to include a display. Thus, in such structures, display 752 can be omitted from system 700.

Antenna 758 can include one or more directional or omnidirectional antennas, including, for example, dipole antennas, monopole antennas, patch antennas, loop antennas, microstrip antennas, or other types of antennas suitable for transmission of radio frequency (RF) signals. In some structures, system 700 does not have to include an antenna. Thus, in such structures, antenna 758 can be omitted from system 700.

I/O controller 750 can include a communication module for wired or wireless communication (e.g., communication through one or more antennas 758). Such wireless communication may include communication in accordance with WiFi communication technique, Long Term Evolution Advanced (LTE-A) communication technique, or other communication techniques.

I/O controller 750 can also include a module to allow system 700 to communicate with other devices or systems in accordance with to one or more of the following standards or specifications (e.g., I/O standards or specifications), including Universal Serial Bus (USB), DisplayPort (DP), High-Definition Multimedia Interface (HDMI), Thunderbolt, Peripheral Component Interconnect Express (PCIe), Ethernet, and other specifications.

Connector 755 can include terminals (e.g., pins) to allow system 700 to receive a connection (e.g., an electrical connection) from an external device (or system). This may allow system 700 to communicate (e.g., exchange information) with such a device (or system) through connector 755. Connector 755 and at least a portion of bus 770 can include conductive lines that conform with at least one of USB, DP, HDMI, Thunderbolt, PCIe, Ethernet, and other specifications.

FIG. 7 shows the components (e.g., devices) of system 700 arranged separately from each other as an example. For example, each of processor 715, memory device 720, memory controller 730, graphics controller 740, and I/O controller 750 can be included in (e.g., formed in or formed on) a separate integrated circuit (IC) chip (e.g., separate semiconductor die or separate IC die). In some structures of system 700, two or more components (e.g., processor 715, memory device 720, graphics controller 740, and I/O controller 750) of system 700 can be included in (e.g., formed in or formed on) the same IC chip (e.g., same semiconductor die), forming a SoC, or alternatively, a SiP.

The illustrations of the apparatuses (e.g., apparatuses 100, 200, 400, 500, and 600, and system 700) and methods (e.g., method of operating apparatuses 100, 200, 400, 500, and 600, and system 700) described above are intended to provide a general understanding of the structure of different embodiments and are not intended to provide a complete description of all the elements and features of an apparatus that might make use of the structures described herein.

Any of the components described above with reference to FIG. 1 through FIG. 7 can be implemented in a number of ways, including simulation via software. Thus, apparatuses (e.g., apparatuses 100, 200, 400, 500, and 600, and system 700) may all be characterized as “modules” (or “module”) herein. Such modules may include hardware circuitry, single-and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The apparatuses and methods described above can include or be included in high-speed computers, communication and signal processing circuitry, single-or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

In the detailed description and the claims, the terms “first,” “second,” and “third,” etc. are used merely as labels, and are not intended to impose numerical requirements on their objects.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the term “adjacent” generally refers to a position of a thing being next to (e.g., either immediately next to or close to with one or more things between them) or adjoining another thing (e.g., abutting it or contacting it (e.g., directly coupled to) it).

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

Described implementations of the subject matter can include one or more features, alone or in combination as illustrated below by way of examples.

Example 1 is an apparatus comprising a first supply node, a conductive pad, and electrostatic discharge (ESD) protection circuitry including a transistor, the transistor including levels of semiconductor materials separated from each other and located one over another over a substrate, wherein respective portions of the levels of semiconductor materials form part of a channel, a source terminal, and a drain terminal of the transistor, a conductive material separated from the channel by a dielectric material and surrounding at least part of the channel, wherein at least a portion of the conductive material forms part of a gate terminal of the transistor, and wherein the gate terminal is coupled to the supply node, the source terminal is coupled to the supply node, and the drain terminal is coupled to the conductive pad.

In Example 2, the subject matter of example 1 includes subject matter wherein the ESD protection circuitry further includes an additional transistor, the additional transistor including additional levels of semiconductor materials separated from each other and located one over another over the substrate, wherein respective portions of the additional levels of semiconductor materials form part of a channel, a source terminal, and a drain terminal of the additional transistor, an additional conductive material separated from the channel of the additional transistor by a dielectric material and surrounding at least part of the channel of the additional transistor, wherein at least a portion of the additional conductive material forms part of a gate terminal of the additional transistor, and wherein the gate terminal of the additional transistor is coupled to an additional supply node, the source terminal of the additional transistor is coupled to the additional supply node, and the drain terminal is coupled to the conductive pad.

In Example 3, the subject matter of example 1 includes subject matter wherein the ESD protection circuitry further includes a third transistor including a gate terminal responsive to receive a first voltage signal, a source terminal coupled to the supply node, and a drain terminal coupled to the conductive pad, and a fourth transistor including a gate terminal to receive a second voltage signal, a source terminal coupled to the additional supply node, and a drain terminal coupled to the conductive pad.

In Example 4, the subject matter of example 3 includes subject matter wherein the third transistor and the fourth transistor are part of an output driver of the apparatus, the output driver including an output node coupled to the conductive pad.

In Example 5, the subject matter of example 1 includes an additional transistor, the additional transistor including a gate terminal coupled to the supply node, a source terminal coupled to the supply node, and a drain terminal coupled to the conductive pad.

In Example 6, the subject matter of any of examples 1-5 includes subject matter wherein the substrate includes a first portion, and a second portion formed between the first portion and the levels of semiconductor materials, wherein the second portion is formed from a dielectric material.

In Example 7, the subject matter of any of examples 1-6 includes subject matter wherein the ESD protection circuitry further includes a capacitor, the capacitor including a first terminal coupled to the supply node and a second terminal coupled to an additional supply node.

In Example 8, the subject matter of any of examples 1-7 includes an input driver, the input driver including an input node coupled to the conductive pad.

In Example 9, the subject matter of any of examples 1-8 includes an interposer, a first integrated circuit (IC) die located over the interposer, and a second IC die located side by side with the first IC die over the interposer, wherein the ESD protection circuitry is included in the first IC die.

In Example 10, the subject matter of any of examples 1-8 includes a first integrated circuit (IC) die, and a second IC die stacked over the first IC die, wherein the ESD protection circuitry is included in one of the first IC die and the second IC die.

In Example 11, the subject matter of any of examples 1-10 includes subject matter wherein the source terminal includes a conductive portion contacting each of the levels of semiconductor materials.

In Example 12, the subject matter of any of examples 1-11 includes subject matter wherein the drain terminal includes a conductive portion contacting each of the levels of semiconductor materials.

In Example 13, the subject matter of any of examples 1-12 includes subject matter wherein each of the levels of semiconductor materials includes a length in a first direction between the source terminal and the drain terminal.

In Example 14, the subject matter of example 13 includes subject matter wherein each of the levels of semiconductor materials includes a width in a second direction perpendicular to the first direction.

In Example 15, the subject matter of any of examples 1-14 includes subject matter wherein the ESD protection circuitry lacks a diode between the conductive pad and the supply node.

In Example 16, the subject matter of any of examples 2-15 includes subject matter wherein the ESD protection circuitry lacks a diode between the conductive pad and the additional supply node.

In Example 17, the subject matter of any of examples 2-15 subject matter wherein the ESD protection circuitry lacks a diode between the conductive pad and the supply node, and a diode between the conductive pad and the additional supply node.

In Example 18, the subject matter of any of examples 1-17 includes subject matter wherein the channel of the transistor is uncoupled to a semiconductor material of the substrate.

In Example 19, the subject matter of examples 1-18 includes subject matter wherein the source terminal of the transistor is uncoupled to a semiconductor material of the substrate.

In Example 20, the subject matter of examples 1-19 includes subject matter wherein the drain terminal of the transistor is uncoupled to a semiconductor material of the substrate.

Example 21 is an apparatus comprising a first supply node, a second supply node, and a conductive pad, and electrostatic discharge (ESD) protection circuitry including a first transistor including a gate terminal to receive a first voltage signal, a source terminal coupled to the first supply node, and a drain terminal coupled to the conductive pad, and a second transistor including a gate terminal to receive a second voltage signal, a source terminal coupled to the second supply node, and a drain terminal coupled to the conductive pad, wherein the first and second transistors are part of an output driver of the apparatus, and the ESD protection circuitry includes levels of semiconductor materials separated from each other and located one over another over a substrate, wherein respective portions of the levels of semiconductor materials form part of a channel, the source terminal, and the drain terminal of one of the first and second transistors, and a conductive material separated from the channel by a dielectric material and surrounding at least part of the channel, wherein at least a portion of the conductive material forms part of the gate terminal of one of the first and second transistors.

In Example 22, the subject matter of example 21 includes subject matter wherein the first transistor includes a p-type transistor, and the second transistor includes an n-type transistor.

In Example 23, the subject matter of any of examples 21-22 example 21 includes subject matter wherein the substrate includes a semiconductor portion, and a dielectric portion formed over the semiconductor portion and between the first semiconductor portion and the levels of semiconductor materials.

In Example 24, the subject matter of any of examples 21-23 includes subject matter wherein the ESD protection circuitry further includes a third transistor including a gate terminal coupled to the first supply node, a source terminal coupled to the first supply node, and a drain terminal coupled to the conductive pad, and a fourth transistor including a gate terminal coupled to the second supply node, a source terminal coupled to the second supply node, and a drain terminal coupled to the conductive pad.

In Example 25, the subject matter of any of examples 21-24 includes subject matter wherein the ESD protection circuitry further includes a capacitor, the capacitor including a first terminal coupled to the first supply node and a second terminal coupled to the second supply node.

In Example 26, the subject matter of any of examples 21-25 includes subject matter wherein the apparatus comprises a system in a package (SiP), the SiP including an integrated circuit (IC) die, wherein the ESD protection circuitry is included in the SiP.

In Example 27, the subject matter of any of examples 21-25 includes a connector and an integrated circuit (IC) die coupled to the connector, the IC die including the ESD protection circuitry, wherein the connector conforms with at least one of Universal Serial Bus (USB), High-Definition Multimedia Interface (HDMI), Thunderbolt, Peripheral Component Interconnect Express (PCIe), and Ethernet specifications.

Example 28 is method of operating an electronic apparatus, the method comprising coupling a gate terminal and a source terminal of a first transistor of an electrostatic discharge (ESD) protection circuitry to a first supply node, coupling a drain terminal of the first transistor to an input/out (I/O) conductive pad, coupling a gate terminal and a source terminal of a second transistor of the ESD protection circuitry to a second supply node, and coupling a drain terminal of the second transistor to the I/O conductive pad, coupling a source terminal of a third transistor of the ESD protection circuitry to the first supply node, coupling a drain terminal of the third transistor to the I/O conductive pad, coupling a source terminal of a fourth transistor of the ESD protection circuitry to the second supply node, and coupling a drain terminal of the fourth transistor to the I/O conductive pad, wherein the third transistor and the fourth transistors are part of an output driver, the output driver including an output node coupled to the I/O conductive pad.

In Example 29, the subject matter of example 28 includes subject matter wherein the ESD protection circuitry further includes a capacitor, the capacitor including a first terminal coupled to the first supply node and a second terminal coupled to the second supply node.

In Example 30, the subject matter of any of examples 28-29 includes subject matter wherein the first transistor, the second transistor, the third transistor, and the fourth transistor are formed over a substrate, and a channel of each of the first transistor, the second transistor, the third transistor, and the fourth transistor is separated from a semiconductor portion of the substrate by a dielectric material.

Example 31 is an apparatus comprising means to implement any of Examples 1-30.

Example 32 is a system to implement any of Examples 1-30.

Example 33 is a method to implement any of Examples 1-30.

The subject matter of Examples 1-33 may be combined in any combination.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

The Abstract is provided to allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus comprising:
a first supply node;
a conductive pad; and
electrostatic discharge (ESD) protection circuitry including a transistor, the transistor including:
levels of semiconductor materials separated from each other and located one over another over a substrate, wherein respective portions of the levels of semiconductor materials form part of a channel, a source terminal, and a drain terminal of the transistor;
a conductive material separated from the channel by a dielectric material and surrounding at least part of the channel, wherein at least a portion of the conductive material forms part of a gate terminal of the transistor; and
wherein the gate terminal is coupled to the supply node, the source terminal is coupled to the supply node, and the drain terminal is coupled to the conductive pad.

2. The apparatus of claim 1, wherein the ESD protection circuitry further includes an additional transistor, the additional transistor including:
additional levels of semiconductor materials separated from each other and located one over another over the substrate, wherein respective portions of the additional levels of semiconductor materials form part of a channel, a source terminal, and a drain terminal of the additional transistor;
an additional conductive material separated from the channel of the additional transistor by a dielectric material and surrounding at least part of the channel of the additional transistor, wherein at least a portion of the additional conductive material forms part of a gate terminal of the additional transistor; and
wherein the gate terminal of the additional transistor is coupled to an additional supply node, the source terminal of the additional transistor is coupled to the additional supply node, and the drain terminal is coupled to the conductive pad.

3. The apparatus of claim 1, wherein the ESD protection circuitry further includes:
a third transistor including a gate terminal responsive to receive a first voltage signal, a source terminal coupled to the supply node, and a drain terminal coupled to the conductive pad; and
a fourth transistor including a gate terminal to receive a second voltage signal, a source terminal coupled to the additional supply node, and a drain terminal coupled to the conductive pad.

4. The apparatus of claim 3, wherein the third transistor and the fourth transistor are part of an output driver of the apparatus, the output driver including an output node coupled to the conductive pad.

5. The apparatus of claim 1, further comprising an additional transistor, the additional transistor including a gate terminal coupled to the supply node, a source terminal coupled to the supply node, and a drain terminal coupled to the conductive pad.

6. The apparatus of claim 1, wherein the substrate includes a first portion, and a second portion formed between the first portion and the levels of semiconductor materials, wherein the second portion is formed from a dielectric material.

7. The apparatus of claim 1, wherein the ESD protection circuitry further includes a capacitor, the capacitor including a first terminal coupled to the supply node and a second terminal coupled to an additional supply node.

8. The apparatus of claim 1, further comprising an input driver, the input driver including an input node coupled to the conductive pad.

9. The apparatus of claim 1, further comprising an interposer, a first integrated circuit (IC) die located over the interposer, and a second IC die located side by side with the first IC die over the interposer, wherein the ESD protection circuitry is included in the first IC die.

10. The apparatus of claim 1, further comprising a first integrated circuit (IC) die, and a second IC die stacked over the first IC die, wherein the ESD protection circuitry is included in one of the first IC die and the second IC die.

11. An apparatus comprising:
a first supply node, a second supply node, and a conductive pad; and
electrostatic discharge (ESD) protection circuitry including:
a first transistor including a gate terminal to receive a first voltage signal, a source terminal coupled to the first supply node, and a drain terminal coupled to the conductive pad; and
a second transistor including a gate terminal to receive a second voltage signal, a source terminal coupled to the second supply node, and a drain terminal coupled to the conductive pad, wherein the first and second transistors are part of an output driver of the apparatus, and the ESD protection circuitry includes:
levels of semiconductor materials separated from each other and located one over another over a substrate, wherein respective portions of the levels of semiconductor materials form part of a channel, the source terminal, and the drain terminal of one of the first and second transistors; and
a conductive material separated from the channel by a dielectric material and surrounding at least part of the channel, wherein at least a portion of the conductive material forms part of the gate terminal of one of the first and second transistors.

12. The apparatus of claim 11, wherein the first transistor includes a p-type transistor, and the second transistor includes an n-type transistor.

13. The apparatus of claim 11, wherein the substrate includes a semiconductor portion, and a dielectric portion formed over the semiconductor portion and between the first semiconductor portion and the levels of semiconductor materials.

14. The apparatus of claim 11, wherein the ESD protection circuitry further includes:
a third transistor including a gate terminal coupled to the first supply node, a source terminal coupled to the first supply node, and a drain terminal coupled to the conductive pad; and
a fourth transistor including a gate terminal coupled to the second supply node, a source terminal coupled to the second supply node, and a drain terminal coupled to the conductive pad.

15. The apparatus of claim 14, wherein the ESD protection circuitry further includes a capacitor, the capacitor including a first terminal coupled to the first supply node and a second terminal coupled to the second supply node.

16. The apparatus of claim 11, wherein the apparatus comprises a system in a package (SiP), the SiP including an integrated circuit (IC) die, wherein the ESD protection circuitry is included in the SiP.

17. The apparatus of claim 11, further comprising a connector and an integrated circuit (IC) die coupled to the connector, the IC die including the ESD protection circuitry, wherein the connector conforms with at least one of Universal Serial Bus (USB), High-Definition Multimedia Interface (HDMI), Thunderbolt, Peripheral Component Interconnect Express (PCIe), and Ethernet specifications.

18. A method comprising:
coupling a gate terminal and a source terminal of a first transistor of an electrostatic discharge (ESD) protection circuitry to a first supply node;
coupling a drain terminal of the first transistor to an input/out (I/O) conductive pad;
coupling a gate terminal and a source terminal of a second transistor of the ESD protection circuitry to a second supply node; and
coupling a drain terminal of the second transistor to the I/O conductive pad;
coupling a source terminal of a third transistor of the ESD protection circuitry to the first supply node;
coupling a drain terminal of the third transistor to the I/O conductive pad;
coupling a source terminal of a fourth transistor of the ESD protection circuitry to the second supply node; and
coupling a drain terminal of the fourth transistor to the I/O conductive pad, wherein the third transistor and the fourth transistors are part of an output driver, the output driver including an output node coupled to the I/O conductive pad.

19. The method of claim 18, wherein the ESD protection circuitry further includes a capacitor, the capacitor including a first terminal coupled to the first supply node and a second terminal coupled to the second supply node.

20. The method of claim 18, wherein:
the first transistor, the second transistor, the third transistor, and the fourth transistor are formed over a substrate; and
a channel of each of the first transistor, the second transistor, the third transistor, and the fourth transistor is separated from a semiconductor portion of the substrate by a dielectric material.
